(19) United States
(12) Patent Application Publication
(10) Pub. No.: US 2026/0262418 A1
(43) Pub. Date: Sep. 3, 2026

(54) DISPLAY PANEL AND DISPLAY DEVICE

(71) Applicant: Wuhan Tianma Micro-Electronics Co., Ltd., Wuhan (CN)

(72) Inventors: Le TA, Wuhan (CN); Zhiqiang XIA, Wuhan (CN); Kang YANG, Wuhan (CN)

(21) Appl. No.: 19/249,296

(22) Filed: Jun. 25, 2025

(30) Foreign Application Priority Data
Feb. 28, 2025 (CN) 202510238759.1

(51) Int. Cl. H10K 59/80; H10K 59/131

(52) U.S. Cl. CPC H10K 59/873; H10K 59/131

(57) ABSTRACT

A display panel and a display device are provided. The non-display area of the display panel is provided with a first retaining wall structure including a first protective layer and a second protective layer; the metal layer of the display panel includes a first metal layer; in the first retaining wall structure, the first protective layer overlaps with the first metal layer, and a distance between a bottom of at least a portion of the second protective layer and the substrate of the display panel is equal to a distance between a bottom of at least a portion of the first protective layer and the substrate; and in a thickness direction of the display panel, an area where the first protective layer and the first metal layer overlap is greater than an area where the first protective layer, the second protective layer and the first metal layer overlap.

### CROSS-REFERENCE TO RELATED APPLICATION

This application claims the priority of Chinese Patent Application No. 202510238759.1, filed on February 28, 2025, the content of which is incorporated by reference in its entirety.

### TECHNICAL FIELD

The present disclosure generally relates to the field of display technologies and, more particularly, relates to a display panel and a display device.

### BACKGROUND

In a display panel, the encapsulation layer usually also includes an organic encapsulation layer. Because organic encapsulation materials have the characteristics of large ink volume or strong capillary fluidity, they are easy to overflow during printing or coating, long strip-shaped protrusions are usually formed in the non-display area. Because the long strip-shaped protrusion is similar to a dam structure, it is called a bank. However, if the bank height is too large, the subsequent wirings are prone to breakage when passing through the bank, affecting the display effect of the display panel.

Therefore, there is a need to reduce the risk of the breakages of the metal wirings. The present disclosed display panels and display devices are direct to solve such a problem and other problems in the arts.

### SUMMARY

One aspect of the present disclosure provides a display panel. The display panel includes a display area; a non-display area surrounding the display area; a substrate; and a metal layer located on one side of the substrate and extending to the non-display area. The non-display area is provided with a first retaining wall structure including a first protective layer and a second protective layer; the metal layer includes a first metal layer; in the first retaining wall structure, the first protective layer overlaps with the first metal layer, and a distance between a bottom of at least a portion of the second protective layer and the substrate is equal to a distance between a bottom of at least a portion of the first protective layer and the substrate; and in a thickness direction of the display panel, an area where the first protective layer and the first metal layer overlap is greater than an area where the first protective layer, the second protective layer and the first metal layer overlap.

Another aspect of the present disclosure includes a display device. The display device includes a display panel. The display panel includes a display area; a non-display area surrounding the display area; a substrate; and a metal layer located on one side of the substrate and extending to the non-display area. The non-display area is provided with a first retaining wall structure including a first protective layer and a second protective layer; the metal layer includes a first metal layer; in the first retaining wall structure, the first protective layer overlaps with the first metal layer, and a distance between a bottom of at least a portion of the second protective layer and the substrate is equal to a distance between a bottom of at least a portion of the first protective layer and the substrate; and in a thickness direction of the display panel, an area where the first protective layer and the first metal layer overlap is greater than an area where the first protective layer, the second protective layer and the first metal layer overlap.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates an exemplary display panel according to various embodiments of the present disclosure;

FIG. 2 illustrates a BB’-sectional view in FIG. 1;

FIG. 3 illustrates a CC’-sectional view in FIG. 1;

FIG. 4 illustrates a cross-sectional view of an exemplary display panel according to various embodiments of the present disclosure;

FIG. 5 illustrates a cross-sectional view of another exemplary display panel according to various embodiments of the present disclosure;

FIG. 6 illustrates a cross-sectional view of another exemplary display panel according to various embodiments of the present disclosure;

FIG. 7 illustrates a cross-sectional view of another exemplary display panel according to various embodiments of the present disclosure;

FIG. 8 illustrates a cross-sectional view of another exemplary display panel according to various embodiments of the present disclosure;

FIG. 9 illustrates a cross-sectional view of another exemplary display panel according to various embodiments of the present disclosure;

FIG. 10 illustrates a cross-sectional view of another exemplary display panel according to various embodiments of the present disclosure;

FIG. 11 illustrates a cross-sectional view of another exemplary display panel according to various embodiments of the present disclosure;

FIG. 12 illustrates a cross-sectional view of another exemplary display panel according to various embodiments of the present disclosure;

FIG. 13 illustrates a cross-sectional view of another exemplary display panel according to various embodiments of the present disclosure;

FIG. 14 illustrates a cross-sectional view of another exemplary display panel according to various embodiments of the present disclosure;

FIG. 15 illustrates a cross-sectional view of another exemplary display panel according to various embodiments of the present disclosure;

FIG. 16 illustrates a DD’-sectional view in FIG. 1;

FIG. 17 illustrates another BB’-sectional view in FIG. 1;

FIG. 18 illustrates another exemplary display panel according to various embodiments of the present disclosure;

FIG. 19 illustrates a cross-sectional view of another exemplary display panel according to various embodiments of the present disclosure; and

FIG. 20 illustrates an exemplary display device according to various embodiments of the present disclosure.

### DETAILED DESCRIPTION

To more clearly understand the above-mentioned purpose, features and advantages of the present disclosure, the scheme of the present disclosure will be further described below. It should be noted that, in the absence of conflict, the embodiments of the present disclosure and the features in the embodiments can be combined with each other.

In the following description, many specific details are set forth to facilitate a full understanding of the present disclosure, but the present disclosure may also be implemented in other ways different from those described herein. Obviously, the embodiments in the specification are only part of the embodiments of the present disclosure, not all of the embodiments.

In the process of manufacturing a display panel, to control the film-forming boundary of the planarization layer during the thin-film encapsulation process and block the flow of the planarization layer, a long strip-shaped protrusion is usually formed in the non-display area by the protective layer, which is similar to a dam structure and is called a bank. The display panel includes multiple metal layers in this area. To prevent the metal layer from being corroded in subsequent processes, such as being corroded by the developer during the development process, a protective layer is usually used to protect the metal layer to prevent the metal layer from being corroded and affecting the quality of the display panel. However, the height of the bank formed by the superposition of each metal layer and each protective layer is too high, and the subsequent wiring is prone to breakage when passing through the bank, affecting the display effect of the display panel. For example, when preparing the touch wirings, the bank height is too high, and the photoresist layer formed on the bank is relatively thin. After exposure, there is no photoresist layer to protect the metal layer, which easily causes the touch wirings to break during etching, affecting the touch effect.

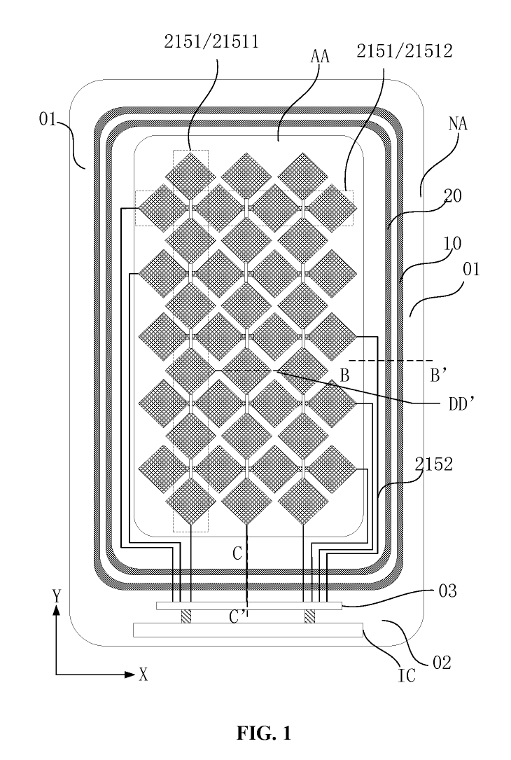

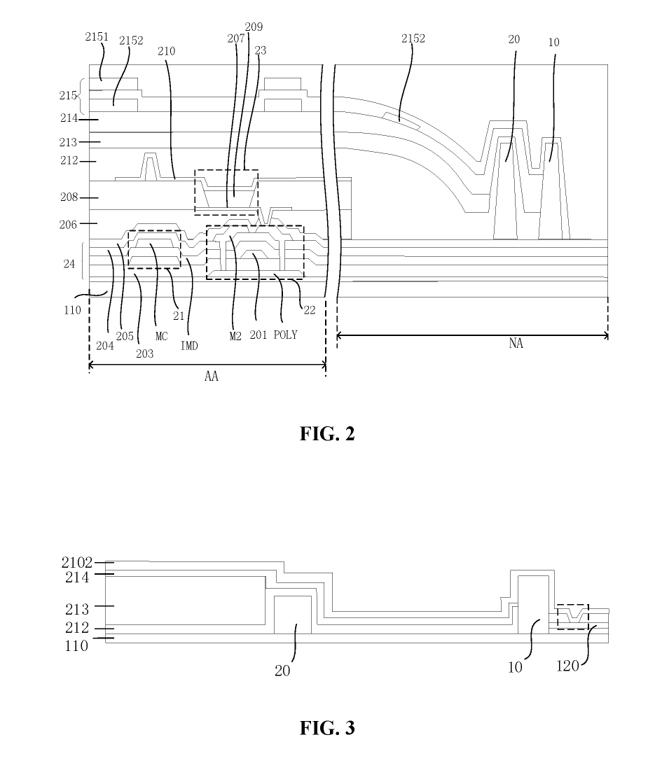

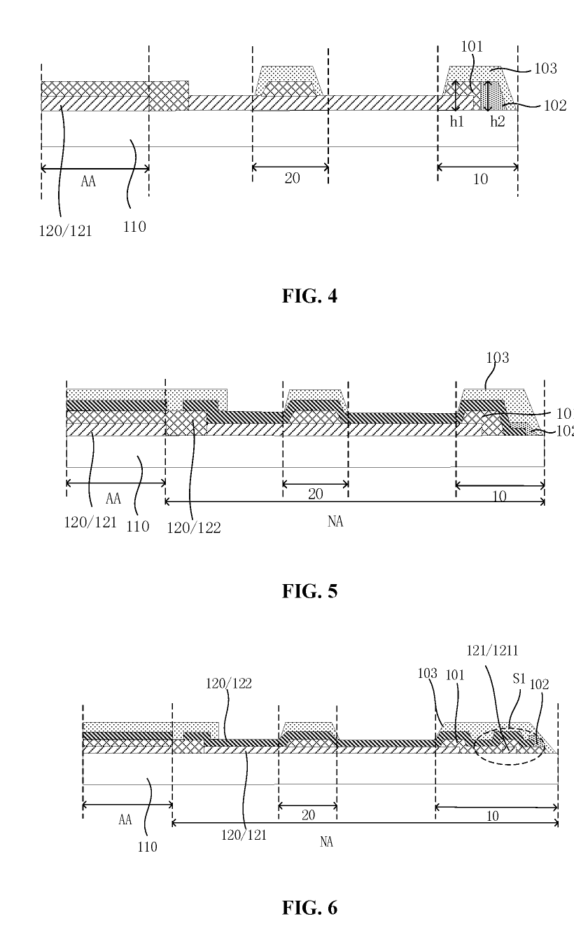

To solve the above problems, the present disclosure provides a display panel and a display device. FIG. 1 is a structural schematic diagram of an exemplary display panel provided by one embodiment of the present disclosure, FIG. 2 is a cross-sectional structural schematic diagram along the BB’ direction in FIG. 1 provided by the embodiment of the present disclosure, FIG. 3 is a cross-sectional structural schematic diagram along the CC’ direction in FIG. 1 provided by the embodiment of the present disclosure, and FIG. 4 is a cross-sectional structural schematic diagram of an exemplary display panel provided by one embodiment of the present disclosure. As shown in FIGS. 1-4, the display panel may include a display area AA and a non-display area NA. The non-display area NA may surround the display area AA, and the non-display area NA may be provided with a first retaining wall structure 10. The display panel may also include a substrate 110 and a metal layer 120. The metal layer 120 may be located on one side of the substrate 110, and the metal layer 120 may extend to the non-display area NA.

The first retaining wall structure 10 may include a first protective layer 101 and a second protective layer 102. The metal layer 120 may include a first metal layer 121, and in the first retaining wall structure 10, the first protective layer 101 may overlap with the first metal layer 121. In the thickness direction of the display panel, the overlap area between the first protective layer 101 and the first metal layer 121 may be greater than the overlap area between the first protective layer 101, the second protective layer 102 and the first metal layer 121.

The structure of the display panel is specifically explained below using FIGS. 1-4 as examples. It should be noted that FIG. 2 shows the film diagram of the left and right frames 01 of the display panel, and FIG. 3 simply illustrates the lower step 02 area of the display panel. The solution provided in the embodiment of the present disclosure is also applicable to different areas of the display panel. Among them, the left and right frames 01 and the lower step area 02 may be both located in the non-display area, and the left and right lower frames may include peripheral circuits, such as vertical shift register (VSR) circuits, etc., and may also include signal lines, such as negative power signal lines PVEE, and may also include some detection circuits such as crack detection lines, etc. The lower step area 02 may be used to bond the control chip IC, and various signal lines may be electrically connected to the control chip IC here, and may also include peripheral circuits, such as multi-way distribution circuits (Demux) circuits, etc.

The display panel may include a substrate 110. The substrate 110 may be a rigid substrate, for example, the material of the substrate 110 may be glass, and the substrate 110 may also be a flexible substrate, for example, the material of the substrate 110 may include one or more combinations of polymer resins of polyethersulfone, polyacrylate, polyetherimide, polyethylene naphthalate, polyethylene terephthalate, polyphenylene sulfide, polyarylate, polyimide, polycarbonate, and cellulose acetate propionate, etc. The material of the substrate 110 is not specifically limited in the embodiment of the present disclosure.

The display panel may be divided into a display area AA and a non-display area NA. The non-display area NA may surround the display area AA. The non-display area NA may be provided with a first retaining wall structure 10, and the first retaining wall structure 10 may have a certain height. To describe the device in the non-display area NA, the proportion of the non-display area NA on the entire display panel is magnified in FIG. 1. The proportion of the display area AA to the non-display area NA in FIG. 1 does not represent its proportion in the real object.

The display panel may include a driving circuit layer 24, a first insulation layer 206 (PLN) and a pixel definition layer 208 (PDL). The driving circuit layer 24 may include a storage capacitor 21 and a transistor 22. FIG. 2 only takes one storage capacitor 21 and one transistor 22 as an example. The transistor 22 may be a thin-film transistor.

The display area AA may include multiple sub-pixels, and the display area AA may achieve a full-color display. In one embodiment of the present disclosure, the display panel may also adopt a display panel with other self-luminous technologies, such as any one of an organic light-emitting diode (OLED) display panel, a micro light-emitting diode (Micro-LED) display panel, and a quantum dot light-emitting diode (QLED) display panel, and the embodiment of the present disclosure does not limit this. FIG. 2 is only a schematic diagram of an OLED display panel as an example.

The sub-pixel may include a light-emitting device 23 and a pixel driving circuit that are electrically connected to each other. The light-emitting device 23 may include a first electrode 207, a light-emitting layer 209, and a second electrode 210 that are arranged oppositely. For example, the first electrode 207 may be an anode, and the second electrode 210 may be a cathode. In some embodiments, the positions of the cathode and the anode may also be interchanged according to the setting of the pixel circuit. The pixel driving circuit may be arranged in the driving circuit layer 24 of the display panel, and the pixel driving circuit 24 may include a storage capacitor 21 and a transistor 22. The number of transistors may be increased according to the setting of the pixel circuit. The pixel driving circuit may refer to as the smallest repeating unit of the circuit structure that drives the corresponding light-emitting element to emit light, such as a 2T1C circuit, a 7T1C circuit, or a 7T2C circuit, etc. The specific working principle is well known to those skilled in the art, and will not be described in detail here.

The driving circuit layer 24 may include multiple sub-film layers, such as display signal lines including power supply voltage signal lines, scan lines and data lines, as well as different structures of thin-film transistors and storage capacitors in the pixel driving circuit, and peripheral circuits located in the non-display area NA may all be formed by different sub-film layers in the driving circuit layer 24.

The display panel may include an encapsulation layer, which may include a first inorganic encapsulation layer 212 (CVD1), an organic encapsulation layer 213 (IJP) and a second inorganic encapsulation layer 214 (CVD2). These layers may be stacked to form a thin-film encapsulation (TFE) structure.

The display panel may also include a plurality of touch electrodes, which may be be set as a single layer or a double layer, and may be formed by transparent metal oxides, such as indium tin oxide (ITO), or a metal mesh formed by metal wires. The embodiment of the present disclosure does not limit the setting method of the touch electrodes.

The setting of the touch electrodes in one embodiment of the present disclosure is described by taking the mutual capacitance method as an example. Referring to FIGS. 1-2, the display panel may include a touch electrode 2151 and a touch wiring 2152. Among them, the first direction may be the X direction, the second direction may be the Y direction, and the first direction may intersect with the second direction. The touch electrode 2151 may include a first touch electrode 21511 and a second touch electrode 21512. The first touch electrodes 21511 extending along the X direction may be arranged along the Y direction, and may include a plurality of first touch electrode 21511 in the X direction, and adjacent first touch electrodes 21511 may be connected to each other through a same layer of metal. The second touch electrodes 21512 extending along the Y direction may be arranged along the X direction, and may include a plurality of second touch electrodes 21512 in the Y direction, and adjacent second touch electrodes 21512 may be connected by a bridge structure. Based on this, two groups of crossed touch electrodes may form a mutual capacitance touch structure. The touch wiring 2152 may be located in the same film layer as the touch electrode 2151, or in the same film layer as the bridge structure, which is not specifically limited in the embodiments of the present disclosure. The touch electrodes 2151 and the touch wirings 2152 in the display area AA may be electrically connected, and the touch wirings 2152 in the display area AA may extend to the non-display area NA along the first direction X and the second direction Y respectively. The non-display area may include left and right frames 01 and a lower step area 02. The lower step area 02 may include a terminal connection area 03, and the terminal connection area 03 may be located on the side away from the first retaining wall structure 10 and away from the display area AA. The touch wiring 2152 may be switched at the terminal connection area 03, and then connected to the control chip IC of the display panel. The control chip IC may receive the touch signal transmitted by the touch wiring 2152 and perform calculation processing. It may also transmit the operation result to the device in the display area AA for display, and provide the required signals for various signal lines.

The above-mentioned organic encapsulation layer 213 may be located between the first inorganic encapsulation layer 212 and the second inorganic encapsulation layer 214. The first inorganic encapsulation layer 212 and the second inorganic encapsulation layer 214 may be prepared by a chemical vapor deposition process and other processes. In the thin-film encapsulation process, the purpose of setting the organic encapsulation layer may be to planarize the display panel, for example, the organic encapsulation layer may be formed by laying the organic encapsulation layer by an ink jet printing (IJP) process. The organic encapsulation material may be spread and leveled quickly. Due to the large amount of ink or the strong fluidity of capillary phenomenon, the organic encapsulation material may be easy to overflow from the edge of the display panel. Therefore, if the organic encapsulation layer overflows during the preparation process, the effect of the thin-film encapsulation will be greatly reduced, and the service life of the display panel will be reduced. Therefore, a first retaining wall structure 10 may be provided in the non-display area NA to prevent the organic encapsulation material from overflowing outward. Normally, the first retaining wall structure 10 may prevent the organic encapsulation material from overflowing. However, to improve the encapsulation reliability, improve the encapsulation effect of the display panel, improve the performance of the display panel, and extend the service life of the display panel, a second retaining wall structure 20 may also be provided to further prevent the organic encapsulation material from overflowing.

In another embodiment, the non-display area NA may be provided with a second retaining wall structure 20, which may be located on the side of the first retaining wall structure 10 adjacent to the display area AA. The second retaining wall structure 20 may also have a certain height, which may prevent the liquid organic encapsulation material from overflowing. It is worth noting that the number of the second retaining wall structures 20 may be multiple. In one embodiment of the present disclosure, only one second retaining wall structure 20 is provided as an example. In different application scenarios, the number of the second retaining wall structures 20 may be set according to actual needs. The embodiment of the present disclosure does not limit the number of the second retaining wall structures 20. The height of the first retaining wall structure 10 may be greater than the height of the second retaining wall structure 20, or it may be equal to the height of the second retaining wall structure 20. In some embodiments, the height of the second retaining wall structure 20 may also be higher than the height of the first retaining wall structure 10. The embodiment of the present disclosure does not impose too many restrictions on the second retaining wall structure 20, and may be specifically designed according to actual needs. The embodiment of the present disclosure may mainly improve the first retaining wall structure 10.

The display panel may also include a metal layer, and the metal layer may be located on one side of the substrate 110. The display area AA may include multiple metal layers, such as the film layer where the first electrode 207 of the light-emitting device 23 is located, the film layer where the second electrode 210 is located, and multiple metal layers in the driving circuit layer 24, etc. The metal layers in the driving circuit layer 24 may include a first source/drain metal layer 201 forming a gate (gate metal layer), a storage capacitor layer MC forming a storage capacitor, a second source/drain metal layer M2 forming a source, a drain and a power signal line of the pixel circuit, and a third source/drain metal layer (not shown in FIG. 2) that may also form a signal line, etc. Because the metal layers of different circuit designs may be different, the examples given here are not intended to limit the metal layers in the display panel.

The display panel may also include an active layer POLY, a gate insulation layer 203 located on the side of the active layer 201 away from the substrate 110, a capacitor insulation layer IMD located on the side of the gate metal layer 201 away from the substrate 110, an interlayer insulation layer 204 located on the side of the capacitor metal layer MC away from the substrate, an organic insulation layer 205 located on the side of the second source/drain metal layer M2 away from the substrate 110, and a first insulation layer 206 located on the side of the organic insulation layer 205 away from the substrate 110. The organic insulation layer 205 and the first insulation layer 206 may both play the role as a planarization film. The display panel may also include a pixel definition layer 208 located on the side of the film layer where the first electrode 207 is located away from the substrate 110, a first inorganic encapsulation layer 212 located on the side of the film layer where the second electrode 210 is located away from the substrate 110, and also include an organic encapsulation layer 213, a second inorganic encapsulation layer 214, and a touch layer 215, etc. In addition, a buffer layer and an inorganic insulation layer may also be provided between the second inorganic encapsulation layer and the touch layer 215, which are not shown in the figure.

The metal layer 120 may extend from the display area AA to the non-display area NA, and a retaining wall structure may be formed in the non-display area. The metal layer 120 here may not specifically refer to a certain metal layer, but refers to at least one layer of the metal layers 120 extending to the non-display area NA. When there are multiple metal layers extending from the display area AA to the non-display area NA, the metal layer may include multiple metal layers, such as the structure corresponding to the left and right frames of the display panel. When there is only one metal layer extending from the display area AA to the display area NA, the metal layer may include one metal layer, such as the structure corresponding to the lower step area 02 of the display panel. The number of metal layers and the corresponding film layers may be determined according to different embodiments.

In different application scenarios, for example, if the second source/drain metal layer M2 in the driving circuit layer 24 extends to the non-display area NA, then the metal layer 120 may include the second source/drain metal layer M2. If the first electrode is an anode and the anode metal layer extends to the non-display area NA, then the metal layer 120 may include the anode metal layer. Therefore, the embodiments of the present disclosure do not limit the specific function and numbers of the metal layers 120.

Thus, the first retaining wall structure 10 may have a certain height to prevent the material forming the organic encapsulation layer 213 from overflowing (the figure includes the first retaining wall structure 10 and the second retaining wall structure 20, and the second retaining wall structure 20 may basically prevent the material from overflowing. If only the first retaining wall structure 10 is set, the first retaining wall structure 10 may block the encapsulation material).

Referring to FIG. 4, the first retaining wall structure 10 may include a first protective layer 101 and a second protective layer 102, and the metal layer 120 may include a first metal layer 121. In the first retaining wall structure 10, the first protective layer 101 may overlap with the first metal layer 121, which may not only protect the first metal layer 121 from being corroded during the subsequent preparation process, but also the overlap of the two may raise the height of the first retaining wall structure 10, thereby playing a better blocking role. In addition, referring to the position of the second protective layer 102 in FIG. 3, the distance between the bottom of at least a portion of the second protective layer and a distance between the bottom of at least a portion of the first protective layer and the substrate may be equal. Under the influence of some preparation processes, the second protective layer 102 may also play a certain protective role on the first metal layer 121.

In the prior art, in the thickness direction of the display panel, the first protective layer, the second protective layer and the first metal layer may all overlap, and the height of the formed first retaining wall structure is too high. In the subsequent preparation process, the step difference generated when the metal wiring passes through the first retaining wall structure 10 is large, so the metal wiring is prone to breakage, affecting the display effect of the display panel. For example, FIG. 3 is a schematic diagram of the non-display area where the touch wiring 2152 crosses the first retaining wall structure 10 and the second retaining wall structure 20. The touch wiring 2152 in FIG. 3 is located at the side of the second inorganic encapsulation layer 214 away from the substrate 110, and the touch wiring 2152 may be a metal wiring. The touch wiring 2152 may need to cross the first retaining wall structure 10 and the second retaining wall structure 20, and at the position of the terminal connection area 03, it may be electrically connected to the metal layer 120 below through the via hole to the driving circuit layer, for example, the metal layer may be a source/drain metal layer, so that the control chip IC may transmit data between the touch wiring 2152 and the touch electrode.

When the touch wiring 2152 needs to cross the first retaining wall structure 10, due to the high height of the first retaining wall structure 10, the step difference generated when the touch wiring 2152 passes through the first retaining wall structure 10 may be large, and the touch wiring 2152 located on the first retaining wall structure 10 away from the surface of the substrate 110 may be thinner and more likely to break.

In the embodiment of the present disclosure, referring to FIG. 4, in the thickness direction of the display panel, the area where the first protective layer 101 and the first metal layer 121 overlap may be larger than the area where the first protective layer 101, the second protective layer 102 and the first metal layer 121 overlap. It can be understood that, at the first retaining wall structure 10, there may be no area where the first protective layer 101, the second protective layer 102 and the first metal layer 121 overlap, and the area with the highest height of the first retaining wall structure 10 may be the area where the first protective layer 101 and the first metal layer 121 overlap. Therefore, by reducing the number of film layers overlapped by the first retaining wall structure 10, the height of the first retaining wall structure 10 may be reduced, and the step difference with the non-first retaining wall structure 10 area may be reduced, so as to avoid the problem that the metal wiring may be easy to break due to the large step difference when passing through the first retaining wall structure 10, thereby improving the display effect and life of the display panel.

It should be noted that FIG. 4 provided in the embodiment of the present disclosure is only an optional implementation method, and there are also a plurality of first retaining wall structures formed by different film layers that meet the above requirements. The subsequent embodiments are explained and illustrated, and it does not mean that only one structure in FIG. 4 meets the requirements. The thickness, length, and proportional relationship of each film layer do not represent the size in the actual product, but are only for illustration. In addition, the protective layer provided in the embodiment of the present disclosure may protect the first protective layer 101 and the second protective layer 102. In some scenarios, the first retaining wall structure 10 of the display panel may also be provided with only the first protective layer 101, and the first metal layer 121 may be protected only by the first protective layer 101.

It can be understood that the metal layer 120 mentioned in the above embodiment may only include the first metal layer 121, that is, there may be no metal layer 120 between the first protective layer 101 and the second protective layer 102. For example, when applied to the lower step area 02 of the display panel, the overall film layer may be less and the retaining wall structure may be shorter. In some other application scenarios, a metal layer 120 may be provided between the first protective layer 101 and the second protective layer 102. For example, the metal layer 120 applied to the left and right frames 01 of the display panel and extending to the non-display area NA may include a first metal layer 121 and a second metal layer 122. There may be also a problem that the first retaining wall structure 10 is too high, which may easily lead to the breakage of the metal wiring passing through it. Therefore, the height of the first retaining wall structure may be reduced by reducing the thickness of the overlap of the first protective layer, the second protective layer and the first metal layer, thereby avoiding the risk of metal wiring breakage. The specific content is described in detail in the subsequent embodiments.

In some embodiments, referring to FIG. 4, the first protective layer 101 may cover the end of the first metal layer 121, and at least a portion of the first protective layer 101 may overlap with the first metal layer 121.

For example, the metal layer 120 may usually extend from the display area AA to the non-display area NA and may be cut off in the non-display area NA, thus the end of the metal layer 120 may be exposed. In the subsequent process of making other film layers, the exposed metal layer may be easily corroded, affecting the yield of the display panel. The embodiment of the present disclosure may provide a first metal layer 121, which may be terminated at the position of the first retaining wall structure 10, so that the end of the first metal layer 121 covered by the first protective layer 101 may be exposed to prevent the end from being corroded. At least a portion of the first protective layer 101 may overlap with the first metal layer 121, which may improve the stability of the structure between the first protective layer 101 and the first metal layer 121, and avoid the situation where the first protective layer 101 may not effectively cover the end of the first metal layer 121.

In one embodiment of the present disclosure, in the thickness direction of the display panel, the first protective layer 101 and the first metal layer 121 may overlap, and there may be no area where the first protective layer 101, the second protective layer 102 and the first metal layer 121 overlap, so the overlap area of the first protective layer 101 and the first metal layer 121 may be greater than the area where the first protective layer 101, the second protective layer 102 and the first metal layer 121 overlap, which may reduce the height of the first retaining wall structure 10, reduce the step difference with the area other than the first retaining wall structure 10, avoid the problem that the metal wiring is easy to break due to the large step difference when passing through the first retaining wall structure 10, and improve the display effect and life of the display panel.

In one embodiment of the present disclosure, the first protective layer 101 may be the first insulation layer 206, such as PLN, and the second protective layer 102 may be the pixel definition layer 208, such as PDL, both of which may play a role in protecting the end of the first metal layer 121. When the second metal layer 122 exists, the protective layer may also protect the end of the second metal layer 122.

It should be noted that the specific materials of the first protective layer and the second protective layer are not limited in the embodiments of the present disclosure, and can be selected according to actual needs.

It is mentioned above that a second metal layer may be set between the first protective layer and the second protective layer. The structure of setting the second metal layer may be described in detail below.

FIG. 5 is a schematic diagram of a cross-sectional view of another exemplary display panel provided in one embodiment of the present disclosure. As shown in FIG. 5, in some embodiments, the metal layer 120 may also include a second metal layer 122. The second metal layer 122 may be located on the side of the first metal layer 121 and the first protective layer 101 away from the substrate 110. In the direction parallel to the display panel, the second metal layer 122 may extend in the direction away from the display area AA, and may overlap with the first protective layer 101 in the direction perpendicular to the display panel.

In one embodiment, the second metal layer 122 may be located on the side of the first metal layer 121 and the first protective layer 101 away from the substrate 110. As shown in FIG. 5, in the direction parallel to the display panel, the second metal layer 122 may extend toward the non-display area NA in the direction away from the display area AA, and may overlap with the first protective layer 101 in the direction perpendicular to the display panel. The first metal layer 121 and the second metal layer 122 may be electrically connected and may serve as signal wrings together, which may reduce the resistance in the signal wirings and help to reduce the problem of excessive voltage drop in the signal wirings. In some embodiments, referring to FIG. 5, the second protective layer 102 may cover the end of the second metal layer 122, and the second protective layer 102 may not overlap with the first protective layer 101 and/or the first metal layer 121.

In one embodiment of the present disclosure, the second metal layer 122 may be terminated at the position of the first retaining wall structure 10. Therefore, to avoid the end of the second metal layer 122 from being exposed, the second protective layer 102 may cover the end of the second metal layer 122 to prevent the end from being corroded. In the thickness direction of the display panel, the second protective layer 102 may not overlap with the first protective layer 101, or the second protective layer 102 may not overlap with the first metal layer 121, or the second protective layer 102 may not overlap with both the first protective layer 101 and the first metal layer 121. Compared with the prior art, in which the first protective layer, the second protective layer, the first metal layer and the second metal layer all overlap in the direction perpendicular to the display panel, in one embodiment of the present disclosure, at least one layer may not overlap with the other three film layers, and the film layers mentioned here refer to the first protective layer 101, the second protective layer 102, the first metal layer 121 and the second metal layer 122. That is, the second protective layer 102 may not overlap with the first protective layer 101 and/or the first metal layer 121. Thereby, the height of the first retaining wall structure 10 may be reduced, the step difference between the first retaining wall structure 10 and the area not having the first retaining wall structure 10 may be reduced, and the problem of the metal wiring passing through the first retaining wall structure 10 being easily broken due to the large step difference may be avoided, thereby improving the display effect and life of the display panel.

In addition, in the above-mentioned embodiment, the first protective layer may extends shorter, and the overall structure may occupy a smaller area. In some other implementations, there may also be a situation where the first protective layer extends longer, which may also be applicable to the method provided in this application. For example, in the left and right frame areas of the display panel, a variety of signal wirings may be arranged, such as the negative power signal line PVEE, and may also include some detection lines such as crack detection lines, etc. The above-mentioned signal wirings may be also formed by metal structures, and the first protective layer may extend longer to cover the metal structure forming the signal wiring.

FIG. 6 is a schematic diagram of a cross-sectional view of another exemplary display panel provided by one embodiment of the present disclosure. As shown in FIG. 6, in some embodiments, the second protective layer 102 may cover the end of the second metal layer 122, and the first protective layer 101 may includes a first region S1 extending in a direction away from the first metal layer 121. In the first region S1, the first protective layer 101 and the second protective layer 102 may at least partially overlap.

In one embodiment of the present disclosure, the first protective layer 101 may extend relatively long to the side away from the display area AA. In addition to covering the end of the first metal layer 121 and partially overlapping with the first metal layer 121, the first protective layer 101 may also extend in a direction away from the first metal layer 121 to form the first region S1. In the first region S1, the first protective layer 101 may have covered the metal structure away from the first metal layer 121. For example, the covered metal structure may be a signal wiring 1211 for transmitting other signals. The embodiment of the present disclosure does not limit the specific type of the signal wiring 1211. The second metal layer 122 may at least cover a portion of the first protective layer 101 in the direction away from the display area AA. If, according to the prior art, a second protective layer is provided on the second metal layer and the second protective layer is used to protect the second metal layer, there will be an area where the first metal layer, the first protective layer, the second metal layer and the second protective layer overlap, resulting in the problem that the first retaining wall structure is relatively high. However, in the embodiment disclosed in the present disclosure, the second protective layer 102 may cover the end of the second metal layer 122. Referring to the above-mentioned film layers in FIG. 6, the first metal layer 121, the first protective layer 101 and the second metal layer 122 may overlap, and the first protective layer 101, the second metal layer 122 and the second protective layer 102 may overlap, and there may be no position where the above-mentioned four film layers overlap each other. Therefore, the height of the first retaining wall structure 10 may be reduced to a certain extent, and the step difference between the first retaining wall structure 10 and the non-first retaining wall structure 10 area may be reduced, so as to avoid the problem that the metal wiring is easily broken due to the large step difference when passing through the first retaining wall structure 10. In addition, the above scheme may also be applicable in other embodiments.

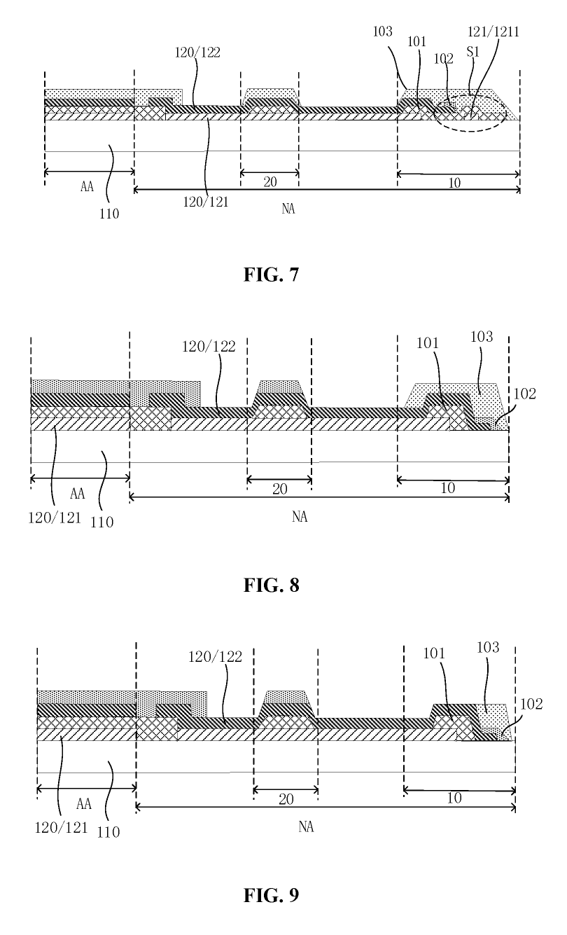

FIG. 7 is a schematic diagram of the cross-sectional view of another exemplary display panel provided in one embodiment of the present disclosure. As shown in FIG. 7, the second metal layer 122 in FIG. 7 may also extend in a direction away from the first metal layer 121 to form a first area S1, but may not cover the signal wiring 1211, but may be terminated before the signal wiring 1211, and the second protective layer 102 may cover the end of the second metal layer 122. It may also be applicable to the above scheme and may bring the same beneficial effect, avoiding the position where the above four film layers overlap each other, and reducing the height of the first retaining wall structure 10.

In some embodiments, continuing to refer to FIG. 4, the maximum thickness of the second protective layer 102 may be less than or equal to the sum of the maximum thicknesses of the first protective layer 101 and the second metal layer 122.

For example, the purpose of the embodiment of the present disclosure may be to reduce the height of the first retaining wall structure 10, avoid the overlap of each metal layer and protective layer to cause the breakage of the metal wiring when passing through the first retaining wall structure 10. If the step difference is too large compared with the area not having the first retaining wall structure, the metal wiring may be easily broken. Therefore, the embodiment of the present disclosure may limit the highest point of the first retaining wall structure 10, that is, the sum of the maximum thicknesses of the first protective layer 101 and the second metal layer 122 may be the highest height of the first retaining wall structure 10. The thicknesses of the remaining film layers in the first retaining wall structure 10 may all be less than or equal to the sum of the maximum thicknesses of the first protective layer 101 and the second metal layer 122. For example, the maximum thickness of the second protective layer 102 may be less than or equal to the sum of the maximum thicknesses of the first protective layer 101 and the second metal layer 122, so as to avoid the second protective layer 102 being too thick to result in the height of the first retaining wall structure 10 being too high.

FIG. 8 is a schematic diagram of a cross-sectional view of another exemplary display panel provided in one embodiment of the present disclosure. As shown in FIG. 8, in one embodiment, the first retaining wall structure 10 may also include a third protective layer 103. The third protective layer 103 may be located at the side of the second protective layer 102 and the second metal layer 122 away from the substrate 110. In the thickness direction of the display panel, the third protective layer 103 may overlap with the second protective layer 102 and/or the first protective layer 101.

In one embodiment, the first retaining wall structure 10 may also include a third protective layer 103. The third protective layer 102 may be located on the side of the second protective layer 102 and the second metal layer 122 away from the substrate 110. The height of the first retaining wall structure 10 may be adjusted by setting the third protective layer 103. Considering the role of the first retaining wall structure 10, to prevent the organic encapsulation material in the display area AA from overflowing outward and affecting the service life of the display panel, the first retaining wall structure 10 with a certain height may be set. The side of the first retaining wall structure 10 away from the substrate may need to be provided with an encapsulation layer, and the third protective layer 103 may play a planarization role, so that the film layers of the display panel may be more closely connected.

In the embodiment shown in FIG. 8, the third protective layer 103 may overlap with the second protective layer 102, and the third protective layer 103 may overlap with the first protective layer 101, but there may be no area where the three layers overlap, which may reduce the height of the first retaining wall structure 10 to a certain extent, and the height of the first retaining wall structure 10 may be adjusted by the third protective layer 103 itself. Therefore, the embodiment of the present disclosure may not only play the original role of blocking the overflow of the organic packaging material, but also avoid the height of the first retaining wall structure 10 being too high and avoid the situation where the metal wiring is broken.

FIG. 9 is a schematic diagram of the cross-sectional view of another exemplary display panel provided in one embodiment of the present disclosure. As shown in FIG. 9, the third protective layer 103 may overlap with the second protective layer 102, but may not overlap with the first protective layer 101, further reducing the height of the first retaining wall structure 10, and there may be no area where the first protective layer 101, the second protective layer 102 and the third protective layer 103 overlap, and it may also play a planarization role.

In another embodiment, the third protective layer 103 may also overlap the first protective layer 101, so that the third protective layer 103 may not overlap with the second protective layer 102. The position of each protective layer may be adjusted according to actual needs.

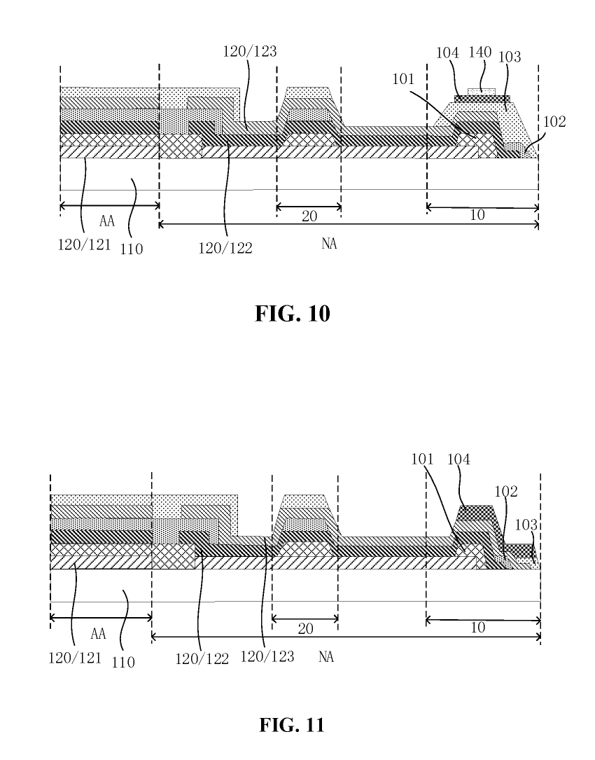

FIG. 10 is a schematic diagram of the cross-sectional view of another exemplary display panel provided in one embodiment of the present disclosure. As shown in FIG. 10, in some embodiments, the metal layer 120 may also include a third metal layer 123. The third metal layer 123 may be located on the side of the second metal layer 122 away from the substrate 110. The third protective layer 103 may cover the end of the third metal layer 123.

In one embodiment, the metal layer 120 may further include a third metal layer 123, and the third metal layer 123 may be located on the side of the second metal layer 122 away from the substrate 110. As shown in FIG. 10, in a direction parallel to the display panel, the third metal layer 123 may extend toward the non-display area NA in a direction away from the display area AA to meet the display panel’s need for the third metal layer 123. For example, in some usage scenarios, the third metal layer 123 may be arranged in the same layer as the anode metal layer. In the non-display area of the display panel, such as the left and right frame areas, the cathode metal layer may need to be overlapped with other metal layers below through the anode metal layer to achieve the negative power signal line PVEE providing the cathode power signal to the cathode metal layer. The third metal layer 123 may be terminated at the position of the first retaining wall structure 10. Therefore, the third protective layer 103 may cover the end of the third metal layer 123, which may prevent the end of the third metal layer 123 from being exposed and being corroded. In the thickness direction of the display panel, the first protective layer 101 and the second protective layer 102 may not overlap. Compared with the prior art, in which the first protective layer, the second protective layer and the third protective layer overlap to form an overly high first retaining wall structure, in the embodiment of the present disclosure, the height of the first retaining wall structure 10 may be reduced to a certain extent, thereby reducing the possibility of metal wiring breaking when passing through the first retaining wall structure 10.

It should be noted that FIG. 10 provided in the embodiment of the present disclosure is only an optional implementation method, and there may be also a variety of first retaining wall structures formed by different film layers that meet the above requirements. The subsequent embodiments are explained and illustrated, which does not mean that only FIG. 10 meets the requirements. The thickness, length, and proportional relationship of each film layer do not represent the size of the actual product, but are only for illustration.

In different embodiments, the third protective layer and the third metal layer may have a variety of optional settings. FIG. 11 is a schematic diagram of a cross-sectional view of another exemplary display panel provided in one embodiment of the present disclosure. As shown in FIG. 11, in some embodiments, the first retaining wall structure 10 may also include a third protective layer 103; and the metal layer 120 may also include a third metal layer 123.

The third metal layer 123 may be located on the side of the second metal layer 122 and the second protective layer 102 away from the substrate 110. In the direction parallel to the display panel, the third metal layer 123 may extend and cover the second protective layer 102 in a direction away from the display area AA, and the third protective layer 103 may cover the end of the third metal layer 123. The third protective layer 103 may not overlap with the first protective layer 101 and/or the second protective layer 102.

The third metal layer 123 in one embodiment of the present disclosure may be located on the side of the second metal layer 122 and the second protective layer 102 away from the substrate 110. As shown in FIG. 11, in the direction parallel to the display panel, the third metal layer 123 may extend toward the non-display area NA in the direction away from the display area AA, and may cover the second protective layer 102, and the third metal layer 123 may be terminated at the position of the first retaining wall structure 10. The position where the third metal layer 123 is terminated may not overlap with the second protective layer 102. To avoid the end of the third metal layer 123 being exposed and corroded, the third protective layer 103 may cover the end of the third metal layer 123. Thus, in the thickness direction of the display panel, the third protective layer 103 may not overlap with the first protective layer 101, or the third protective layer 103 may not overlap with the second protective layer 102, or the first protective layer 101, the second protective layer 102 and the third protective layer 103 may not overlap, that is, the third protective layer 103 may not overlap with the first protective layer 101 and/or the second protective layer 102. Compared with the prior art, in which the first protective layer, the second protective layer and the third protective layer are all overlapped to form an overly high first retaining wall structure, in the embodiment of the present disclosure, the height of the first retaining wall structure 10 may be greatly reduced, so the possibility of the metal wiring breaking when passing through the first retaining wall structure 10 may be reduced.

It should be noted that FIG. 11 provided in the embodiment of the present disclosure is only an optional implementation method, and there may also be a variety of first retaining wall structures formed by different film layers that meet the above requirements. The subsequent embodiments may be explained and illustrated, which may not mean that only FIG. 11 meets the requirements. The thickness, length, and proportional relationship of each film layer do not represent the size in the actual product, but are only for illustration.

In some embodiments, continuing to refer to FIG. 10, the first retaining wall structure 10 may also include a fourth protective layer 104. The fourth protective layer 104 may overlap with the first protective layer 101, the second protective layer 102 and the third protective layer 103.

In some embodiments, the first retaining wall structure 10 may also include a fourth protective layer 104, which may protect the film layers located on the side adjacent to the substrate 110 and may also adjust the height of the first retaining wall structure 10. Referring to FIG. 10, the fourth protective layer 104 may be located on the side of the third protective layer 103 away from the substrate 110, the fourth protective layer 104 may overlap with the first protective layer 101, the fourth protective layer 104 may overlap with the second protective layer 102, and the fourth protective layer 104 may overlap with the third protective layer 103, but there may be no overlapping area among the first protective layer 101, the second protective layer 102, the third protective layer 103 and the fourth protective layer 104 in the first retaining wall structure 10.

Similarly, referring to FIG. 11 , the fourth protective layer 104 may be located on the side of the third metal layer 123 and the third protective layer 103 away from the substrate 110, the fourth protective layer 104 may overlap with the first protective layer 101, the fourth protective layer 104 may overlap with the second protective layer 102, and the fourth protective layer 104 may overlap with the third protective layer 103, but there may be no overlapping area among the first protective layer 101, the second protective layer 102, the third protective layer 103 and the fourth protective layer 104 in the first retaining wall structure 10. Therefore, the height of the first retaining wall structure 10 may be reduced, which may reduce the possibility of metal wiring breaking when passing through the first retaining wall structure 10, and improve the service life of the display panel.

As mentioned above, there may be differences in the film layer structure of different areas of the non-display area of the display panel. For example, the lower step area may need to change the touch wiring to make it electrically connected to the driving circuit layer. In this case, there may be fewer metal layers extending to the lower step area, for example, only the first metal layer. There may be more metal layers extending to the left and right frames, such as the first metal layer and the second metal layer. The first protective layer may be required to protect the end of the first metal layer, and the second protective layer may be required to protect the end of the second metal layer. When preparing the protective layer, the entire layer may need to be prepared, and then etching may be performed. Therefore, there may be a possibility that only the first metal layer includes two film layers: the first protective layer and the second protective layer. In some embodiments, referring to FIG. 4, the second protective layer 102 may be in contact with the first protective layer 101, and the second protective layer 102 may be located at the side of the first protective layer 101 away from the display area AA.

In one embodiment of the present disclosure, the first protective layer 101 may be in contact with the second protective layer 102, and the second protective layer 102 may be located at the side of the first protective layer 101 away from the display area AA, which may increase the width of the first retaining wall structure 10 in the width direction of the display panel and improve the blocking ability. Moreover, it can be seen that, in the thickness direction of the display panel, the first protective layer 101 and the second protective layer 102 may not overlap, thereby reducing the thickness of the first retaining wall structure 10. Such a configuration may avoid the metal wiring to break easily when passing through the first retaining wall structure 10 causing by the situation that each metal layer and protective layer all overlap and there is a large step difference between the overlapping area and the non-first retaining wall structure 10 area. In addition, the width of the first retaining wall structure 10 may be increased in the width direction of the display panel to improve the blocking ability.

The disclosed embodiment may not limit the positional relationship between the first protective layer, the second protective layer and the first metal layer. The attached drawings are only for illustration and may be set according to actual needs.

In some embodiments, referring to FIG. 4, the maximum distance between the side of the second protective layer 102 facing away from the substrate 110 and the substrate 110 may be equal to the maximum distance between the side of the first protective layer 101 facing away from the substrate 110 and the substrate 110.

In one embodiment, because the first protective layer 101 and the second protective layer 102 may be located in the same plane, when preparing the above-mentioned film layers, the maximum distance h1 between the side of the second protective layer 102 facing away from the substrate 110 and the substrate 110 may be equal to the maximum distance h2 between the side of the first protective layer 101 facing away from the substrate 110 and the substrate 110. At this time, the surface of the first protective layer 101 facing away from the substrate 110 may be flush with the surface of the second protective layer 102 facing away from the substrate 110, which may be equivalent to the surface of the first retaining wall structure 10 facing away from the substrate 110 being relatively flat. When the metal wiring passes through this place, there may be no step difference on the surface of the first retaining wall structure 10, which may reduce the possibility of metal wiring breakage.

In some embodiments, referring to FIG. 4, the first retaining wall structure 10 may also include a third protective layer 103. The third protective layer 103 may cover the first protective layer 101 and the second protective layer 102 and may cover at least a portion of the first metal layer 121.

In one embodiment, the first retaining wall structure 10 may also include a third protective layer 103, which may be located on the side of the first protective layer 101, the second protective layer 102 and the second metal layer 122 away from the substrate 110. The third protective layer 103 may cover the first protective layer 101 and the second protective layer 102 and may cover at least a portion of the first metal layer 121. By setting the third protective layer 103, the height of the first retaining wall structure 10 may be adjusted, and the first protective layer 101 and the second protective layer 102 may be protected. Considering the role of the first retaining wall structure 10, to prevent the organic encapsulation material in the display area AA from overflowing outward and affecting the service life of the display panel, a first retaining wall structure 10 with a certain height may be set. Therefore, the height of the first retaining wall structure 10 may also be adjusted by the third protective layer 103. The third protective layer 103 may also play a planarization role, so that the contact between the various film layers of the display panel may be closer, and may also cover the metal layer and protective layer below to protect the various film layers below.

In the embodiment shown in FIG. 4, the third protective layer 103 may overlap with the second protective layer 102, and the third protective layer 103 may overlap with the first protective layer 101, but there may be no overlap area between the three layers, which may reduce the height of the first retaining wall structure 10 to a certain extent, effectively prevent the overflow of organic packaging materials, and may avoid the height of the first retaining wall structure 10 being too high, avoid the situation of metal wiring being broken, and may also protect other film layers.

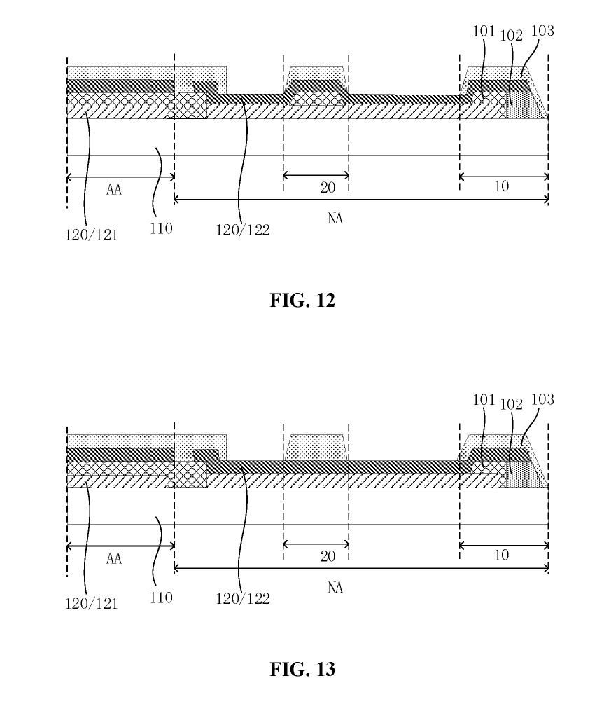

FIG. 12 is a schematic diagram of the cross-sectional view of another exemplary display panel provided in one embodiment of the present disclosure, and FIG. 13 is a schematic diagram of the cross-sectional view of another exemplary display panel provided in one embodiment of the present disclosure. As shown in FIG. 12 and FIG. 13, the metal layer 120 may also include a second metal layer 122. The second metal layer 122 may be located on the side of the first metal layer 121, the first protective layer 101 and the second protective layer 102 away from the substrate 110, and the third protective layer 103 may cover at least a portion of the second metal layer 122.

In one embodiment, the metal layer may also include a second metal layer 122, which may be located on the side of the first metal layer 121, the first protective layer 101 and the second protective layer 102 away from the substrate 110. As shown in FIG. 12, in the direction parallel to the display panel, the second metal layer 122 may extend toward the non-display area NA in the direction away from the display area AA to meet the display panel’s need for the second metal layer 122. The third protective layer 103 may cover the end of the second metal layer 122, which may prevent the end of the second metal layer 122 from being exposed and corroded in subsequent processes. In addition, the third protective layer 103 may cover at least a portion of the second metal layer 122, and the third protective layer 103 may play a planarization role, and the thickness of the first retaining wall structure 10 may be adjusted by adjusting its thickness.

It is understandable that the embodiment of the present disclosure may not impose any specific restrictions on the structure of the second retaining wall structure 20. As shown in FIG. 12, the second retaining wall structure 20 may be higher than the first retaining wall structure 10, and may include a first protective layer 101, a first metal layer 121, a second metal layer 122, and a third protective layer 103 at the second retaining wall structure 20. In some other embodiments, the second retaining wall structure 20 may also be lower than the first retaining wall structure 10, and may include a first metal layer 121, a second metal layer 122, and a third protective layer 103 at the second retaining wall structure 20. As described in the foregoing embodiments of the present disclosure, there may be no specific restriction on the height relationship between the first retaining wall structure and the second retaining wall structure, and actual needs may be met. Therefore, there may be many different structures of the second retaining wall structure, which are not listed here one by one.

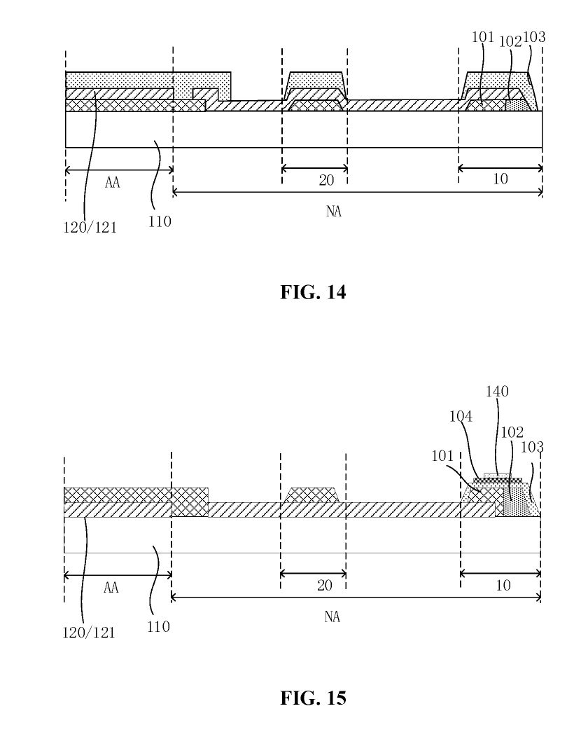

FIG. 14 is a schematic diagram of a cross-sectional view of another exemplary display panel provided in one embodiment of the present disclosure. As shown in FIG. 14, the first metal layer 121 may be located on the side of the first protective layer 101 and the second protective layer 102 away from the substrate 110, and the third protective layer 103 may cover the end of the first metal layer 121.

In one embodiment, the first metal layer 121 may be located on the side of the first protective layer 101 and the second protective layer 102 away from the substrate 110, and the first metal layer 121 may be terminated at the position of the first retaining wall structure 10. Therefore, the third protective layer 103 may cover the end of the first metal layer 121, which may avoid the end of the first metal layer 121 from being exposed and corroded. In the thickness direction of the display panel, the first protective layer 101 and the second protective layer 102 may not overlap, so there may be no area where the first protective layer, the second protective layer, the third protective layer and the first metal layer overlap in the prior art. Therefore, compared with the prior art, the embodiment of the present disclosure may reduce the height of the first retaining wall structure 10, reduce the step difference between the first retaining wall structure 10 and the area not having a first retaining wall structure, avoid the problem that the metal wiring is easily broken due to the large step difference when passing through the first retaining wall structure 10, and improve the display effect and life of the display panel.

In some embodiments, referring to FIG. 14, the first metal layer 121 may be located on the side of the first protective layer 101 facing the substrate 110, and the first protective layer 101 may cover the end of the first metal layer 121.

In one embodiment, the first metal layer 121 may be located on the side of the first protective layer 101 facing the substrate 110, and the first metal layer 121 may be terminated at the position of the first retaining wall structure 10. The first protective layer 101 may cover the end of the first metal layer 121, which may avoid the end of the first metal layer 121 from being exposed and corroded. Although the first metal layer 121 may overlap with the first protective layer 101, neither of them may overlap with the second protective layer 102, which may reduce the height of the first retaining wall structure 10 to a certain extent, may reduce the step difference between the first retaining wall structure 10 and the area not having first retaining wall structure, avoid the problem of easy breakage of metal wiring passing through the first retaining wall structure 10 due to excessive step difference, and may improve the display effect and life of the display panel.

FIG. 15 is a schematic diagram of a cross-sectional view of another exemplary display panel provided by one embodiment of the present disclosure. As shown in FIG. 15, in some embodiments, the first retaining wall structure 10 may further include a fourth protective layer 104. The fourth protective layer 104 may be located on the side of the third protective layer 103 away from the substrate 110, and may cover at least a portion of the third protective layer 103.

In one embodiment, the first retaining wall structure 10 may further include a fourth protective layer 104. The fourth proactive layer 104 may protect the film layers located on the side adjacent to the substrate 110 and may also adjust the height of the first retaining wall structure 10. Referring to FIG. 15, the fourth protective layer 104 may be located on the side of the third protective layer 103 away from the substrate 110, and the fourth protective layer 104 may cover at least a portion of the third protective layer 103. In the first retaining wall structure 10 provided by the embodiment of the present disclosure, there may be no region where the first protective layer 101, the second protective layer 102, the third protective layer 103, and the fourth protective layer 104 overlap. Therefore, the height of the first retaining wall structure 10 may be reduced, which may reduce the possibility of metal wiring breaking when passing through the first retaining wall structure 10, and improve the service life of the display panel. In addition, the height of the first retaining wall structure 10 may also be adjusted by the fourth protective layer 104 to prevent the height of the first retaining wall structure 10 from failing to effectively block the overflow of the liquid organic encapsulation material in the display area.

In some embodiments, the metal layer may include an anode metal layer and/or at least one source/drain metal layer. The anode metal layer may be located on the side of the source/drain metal layer away from the substrate.

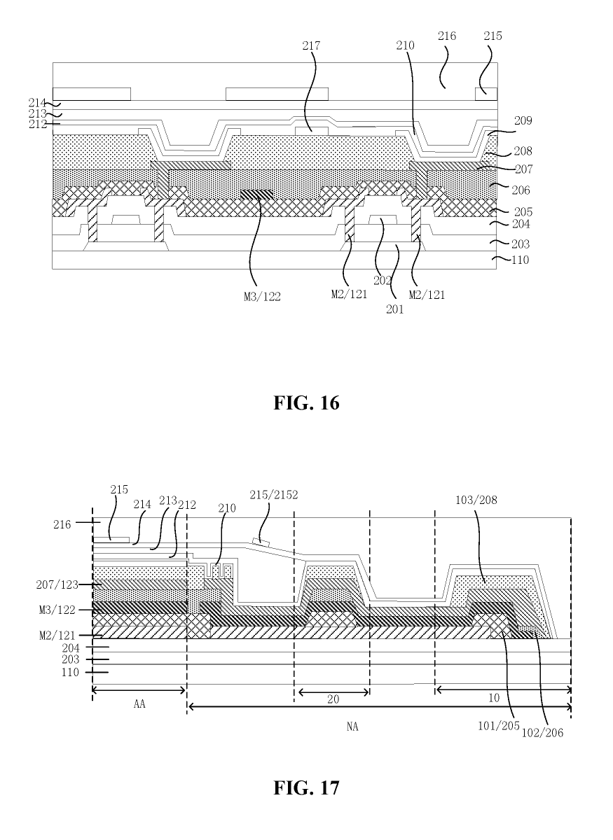

FIG. 16 is a schematic diagram of a cross-sectional view along DD’ direction in FIG. 1 provided by one embodiment of the present disclosure, and FIG. 17 is another schematic diagram of a cross-sectional view along BB’ direction in FIG. 1 provided by one embodiment of the present disclosure. FIG. 16 and FIG. 17 are taken from the display panel provided by the same embodiment, and each film layer corresponds. As shown in FIGS. 16-17, the metal layer 120 extending from the display area AA of the display panel to the non-display area NA may include a first metal layer 121, a second metal layer 122, and a third metal layer 123. The first metal layer 121 may be the second source/drain metal layer M2, the second metal layer 122 may be the third source/drain metal layer M3, the third metal layer 123 may be arranged in the same layer as the anode metal layer, and the anode metal layer may be located on the side of each source/drain metal layer away from the substrate 110. The second source/drain metal layer M2 may be used to form the source, drain and power signal wirings of the pixel circuit, and the third source/drain electrode layer M3 may also be used to form the signal wiring of the pixel circuit. In some scenarios, the cathode metal layer may need to overlap with the anode metal layer below through a via hole, and then overlap with other metal layers below through the anode metal layer, so as to achieve the purpose of the negative power signal line PVEE providing the cathode power signal to the cathode metal layer.

In addition, the display area of the display panel in one embodiment of the present disclosure may also include a first source/drain metal layer 202 for forming the gate of the pixel circuit; and may also include an active layer 201, a gate insulation layer 203, an interlayer insulation layer 204, an organic insulation layer 205 (BPL), a first insulation layer 206 (PLN), a pixel definition layer 208 (PDL), a light-emitting layer 209, a cathode metal layer 210 (cathode), a first inorganic encapsulation layer 212 (CVD1), an organic encapsulation layer 203 (IJP), a second inorganic encapsulation layer 214 (CVD2), a touch layer 215, an optical adhesive layer 216, and a support layer 217. In some embodiments, the display panel may also include other film layer structures, for example, a buffer layer and an inorganic insulation layer may also be provided between the second inorganic encapsulation layer and the touch layer, which may not all be shown in the figure. The above embodiment is only used as an example to illustrate only the local structure or local film layer related to the embodiment of the present disclosure. Other omitted structures or film layers are not described in detail here, and the specific film layer may be set according to the actual situation.

Referring to FIG. 17, in the non-display area provided in the embodiment of the present disclosure, the metal layer 120 may include a first metal layer 121, a second metal layer 122, and a third metal layer 123. That is, the first metal layer 121 may be the second source/drain metal layer M2, the second metal layer 122 may be the third source/drain metal layer M3, and the third metal layer 123 may be the anode metal layer. The first protective layer 101 may be the organic insulation layer 205, the second protective layer 102 may be the first insulation layer 206, and the third protective layer 103 may be the pixel definition layer 208. In the non-display area, the end of the second source/drain metal layer M2 may be covered by the organic insulation layer 205, and the end of the third source/drain metal layer M3 may be covered by the first insulation layer 206. The anode metal layer may be located on the side of the second source/drain metal layer M2 and the third source/drain metal layer M3 away from the substrate 110. The end of the anode metal layer may be covered by the pixel definition layer 208. The organic insulation layer 205 may not overlap with the first insulation layer 206, reducing the number of film layers overlapped by the first retaining wall structure, so as to reduce the height of the first retaining wall structure, reduce the step difference between the first retaining wall structure and the area not having first retaining wall structure, and avoid the problem that the metal wiring is easy to break due to the large step difference when passing through the first retaining wall structure, thereby improving the display effect and life of the display panel.

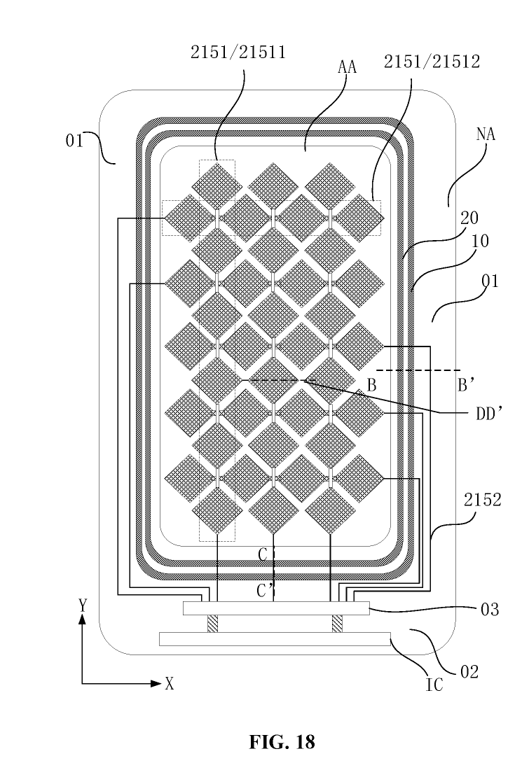

The position shown in FIG. 17 may belong to the left and right frames, and no punching design may be performed at this position of the structure to make the touch wiring and the metal layer below to be electrically connected by switching lines. However, in some other application scenarios, such as the structure shown in FIG. 18, which is a structural schematic diagram of another exemplary display panel provided by one embodiment of the present disclosure, at the left and right frames of the display panel, holes may also be punched to make the touch wiring overlap with the metal layer below through the via hole. It should be noted that the film layer thickness provided in the embodiment of the present disclosure may not represent the thickness of each film layer of the actual display panel, and the attached figure only shows the position of each film layer.

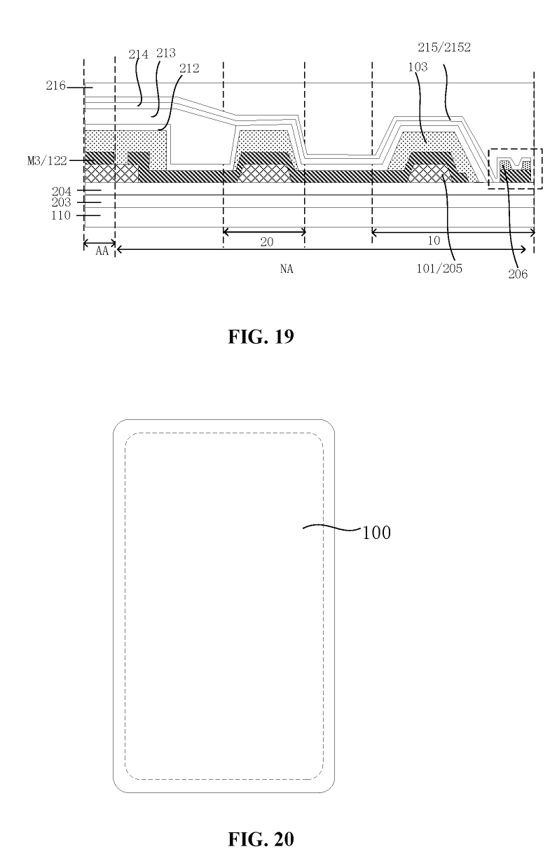

FIG. 19 is a schematic diagram of the cross-sectional view of another exemplary display panel provided by one embodiment of the present disclosure. As shown in FIG. 19, a schematic diagram of the structure of the touch wiring switching area of the display panel is shown, the touch wiring switching area may include a first retaining wall structure 10 and a second retaining wall structure 20. In this area, the touch wiring 2152 may need to be electrically connected to the metal layer M3 through the via hole here, so that the control chip IC may transmit data between the touch wiring 2152 and the touch electrode. FIG. 19 can not only illustrate that the touch wiring in the lower step area of the display panel is punched and switched to the metal layer M3, but also conforms to the punching and switching of the touch wiring to M3 at the left and right frames in FIG. 18.

It should be noted that the embodiment of the present disclosure is only an optional film layer design scheme, and there may be also a plurality of different film layers that form the first retaining wall structure to meet the above requirements. The thickness, length, and proportional relationship of each film layer may not represent the size in the actual product; and they are only for illustration. The specific meaning of each film layer may refer to the explanation of each film layer in FIG. 16, and may be designed according to actual needs.

In some embodiments, at least one of the first protective layer and the second protective layer may be an organic film layer. Referring to FIGS. 16-17, the first protective layer 101 may be an organic film layer, such as an organic insulation layer 205, which may play the role of insulation and protection of the display panel. The first protective layer 101 may be formed by an organic film layer. The organic material may have a certain toughness and stress cracking resistance, and may effectively protect the display panel. The second protective layer 102 may also be an organic film layer, such as the first insulation layer 206, which may planarize the film layer, make the display panel smoother, reduce the step difference everywhere, and play a protective role. The first protective layer 101 and the second protective layer 102 may also be all organic film layers, which may planarize the film layer and protect the display panel together. The first protective layer 101 and the second protective layer 102 may include acrylic polymers, silicon polymers, etc., and may be formed by inkjet printing, or spraying, etc.

In some embodiments, referring to FIG. 15, the first retaining wall structure 10 may also include a support column 140. The support column 140 may be located on the side of the fourth protective layer 104 away from the substrate 110.

In one embodiment, the first retaining wall structure 10 may also be provided with a support column 140. The support column 140 may support the film layer in the display panel and enhance the strength of the display panel. The support column 140 may be made of an acrylic polymer, or a silicon polymer, etc., and may also be formed on the side of the fourth protective layer 104 away from the substrate 110 by inkjet printing, or spraying, etc.

The present disclosure also provides a display device. The display device may include a display panel as in any of the above display panel embodiments. Therefore, the display device may have the technical features of the display panel provided in the embodiments of the present disclosure, and may achieve the beneficial effects of the display panel provided in the embodiments of the present disclosure. The similarities may be referred to the above description of the display panel provided in the embodiments of the present disclosure, and will not be repeated here.

FIG. 19 is a schematic diagram of the structure of an exemplary display device provided in one embodiment of the present disclosure. As shown in FIG. 19, the display device may include a display panel 100 provided in any of the above embodiments of the present disclosure. The embodiment provided in FIG. 19 only takes a mobile phone as an example to illustrate the display device. It can be understood that the display device provided in the embodiment of the present disclosure may be any electronic product with a display function, including but not limited to the following categories: mobile phones, televisions, laptops, desktop displays, tablet computers, digital cameras, smart bracelets, smart glasses, vehicle displays, medical equipment, industrial control equipment, and touch interactive terminals, etc., and the embodiments of the present disclosure do not specifically limit this.

The display device provided in the embodiments of the present disclosure may include the above-mentioned display panel, so it may also solve the same technical problems as the above-mentioned display panel embodiment and achieve the same technical effects, which will not be repeated here.

The technical solution provided by the present disclosure has the following advantages. In the display panel provided by the present disclosure, in the first retaining wall structure, the first protective layer and the first metal layer may overlap, and in the thickness direction of the display panel, the area of the overlap between the first protective layer and the first metal layer may be greater than the area of the overlap between the first protective layer, the second protective layer and the first metal layer. The present disclosure may reduce the thickness of the overlap between the first protective layer, the second protective layer and the first metal layer, thereby reducing the height of the first retaining wall structure in the thickness direction of the display panel. When the metal wiring passes through the first retaining wall structure, due to the relatively lower height of the first retaining wall structure, the step difference of the metal wiring when crossing this position may be small, which may greatly avoid the risk of metal wiring breakage.

It should be noted that in this disclosure, relational terms such as “first” and “second” are only used to distinguish one entity or operation from another entity or operation, and do not necessarily require or imply any such actual relationship or order between these entities or operations. Moreover, the terms “include”, “comprise” or any other variant thereof are intended to cover non-exclusive inclusion, so that a process, method, article or device including a series of elements includes not only those elements, but also other elements not explicitly listed, or also includes elements inherent to such a process, method, article or device. In the absence of further restrictions, an element defined by the sentence “comprising a ...” does not exclude the presence of other identical elements in the process, method, article or device comprising the element.

The above is only a specific implementation of the present disclosure, so that those skilled in the art can understand or implement the present disclosure. Various modifications to these embodiments will be obvious to those skilled in the art, and the general principles defined herein can be implemented in other embodiments without departing from the spirit or scope of the present disclosure. Therefore, the present disclosure will not be limited to the embodiments described herein, but will conform to the widest scope consistent with the principles and novel features disclosed herein.

What is claimed is:

1. A display panel, comprising:
a display area;
a non-display area surrounding the display area;
a substrate; and
a metal layer located on one side of the substrate and extending to the non-display area,
wherein:
the non-display area is provided with a first retaining wall structure including a first protective layer and a second protective layer;
the metal layer includes a first metal layer;
in the first retaining wall structure, the first protective layer overlaps with the first metal layer, and a distance between a bottom of at least a portion of the second protective layer and the substrate is equal to a distance between a bottom of at least a portion of the first protective layer and the substrate; and
in a thickness direction of the display panel, an area where the first protective layer and the first metal layer overlap is greater than an area where the first protective layer, the second protective layer and the first metal layer overlap.

2. The display panel according to claim 1, wherein:
the first protective layer covers an end of the first metal layer; and
at least a portion of the first protective layer overlaps with the first metal layer.

3. The display panel according to claim 2, wherein the metal layer further comprises:
a second metal layer located on a side of the first metal layer and the first protective layer away from the substrate,
wherein:
in a direction parallel to the display panel, the second metal layer extends in a direction away from the display area; and
in a direction perpendicular to the display panel, the second metal layer overlaps with the first protective layer.

4. The display panel according to claim 3, wherein:
the second protective layer covers an end of the second metal layer; and
the second protective layer does not overlap with the first protective layer and/or the first metal layer.

5. The display panel according to claim 3, wherein:
the second protective layer covers an end of the second metal layer;
the first protective layer includes a first region extending in a direction away from the first metal layer; and
in the first region, the first protective layer at least partially overlaps with the second protective layer.

6. The display panel according to claim 3, wherein the first retaining wall structure further comprises:
a third protective layer located on a side of the second protective layer and the second metal layer away from the substrate, wherein, in a thickness direction of the display panel, the third protective layer overlaps with the second protective layer and/or the first protective layer.

7. The display panel according to claim 6, wherein the metal layer further comprises:
a third metal layer located on a side of the second metal layer away from the substrate, wherein the third protective layer covers an end of the third metal layer.

8. The display panel according to claim 3, wherein:
a maximum thickness of the second protective layer is less than or equal to a sum of maximum thicknesses of the first protective layer and the second metal layer.

9. The display panel according to claim 4, wherein:
the first retaining wall structure also includes a third protective layer;
the metal layer also includes a third metal layer;
the third metal layer is located on a side of the second metal layer and the second protective layer away from the substrate;
in a direction parallel to the display panel, the third metal layer extends in a direction away from the display area and covers the second protective layer;
the third protective layer covers an end of the third metal layer; and
the third protective layer does not overlap with the first protective layer and/or the second protective layer.

10. The display panel according to claim 9, wherein the first retaining wall structure further comprises:
a fourth protective layer overlapping with the first protective layer, the second protective layer and the third protective layer.

11. The display panel according to claim 1, wherein:
the second protective layer is in contact with the first protective layer; and
the second protective layer is located at a side of the first protective layer away from the display area.

12. The display panel according to claim 11, wherein:
a maximum distance between a side of the second protective layer facing away from the substrate and the substrate is equal to a maximum distance between a side of the first protective layer facing away from the substrate and the substrate.

13. The display panel according to claim 11, wherein the first retaining wall structure further comprises:
a third protective layer covering the first protective layer and the second protective layer and at least a portion of the first metal layer.

14. The display panel according to claim 13, wherein the metal layer further comprises:
a second metal layer located on a side of the first metal layer, the first protective layer and the second protective layer away from the substrate, wherein the third protective layer covers at least a portion of the second metal layer.

15. The display panel according to claim 13, wherein:
the first metal layer is located on a side of the first protection layer and the second protection layer facing away from the substrate; and
the third protection layer covers an end of the first metal layer.

16. The display panel according to claim 13, wherein:
the first metal layer is located on a side of the first protection layer facing the substrate; and
the first protection layer covers an end of the first metal layer.

17. The display panel according to claim 13, wherein the first retaining wall structure further comprises:
a fourth protective layer located on a side of the third protective layer away from the substrate and covering at least a portion of the third protective layer.

18. The display panel according to claim 1, wherein the metal layer comprises:
an anode metal layer and/or at least one source/drain metal layer, wherein the anode metal layer is located on a side of the source/drain metal layer facing away from the substrate.

19. The display panel according to claim 1, wherein:
at least one of the first protective layer and the second protective layer is an organic layer.

20. A display device, comprising:
a display panel, including:
a display area;
a non-display area surrounding the display area;
a substrate; and
a metal layer located on one side of the substrate and extending to the non-display area,
wherein:
the non-display area is provided with a first retaining wall structure including a first protective layer and a second protective layer;
the metal layer includes a first metal layer;
in the first retaining wall structure, the first protective layer overlaps with the first metal layer, and a distance between a bottom of at least a portion of the second protective layer and the substrate is equal to a distance between a bottom of at least a portion of the first protective layer and the substrate; and
in a thickness direction of the display panel, an area where the first protective layer and the first metal layer overlap is greater than an area where the first protective layer, the second protective layer and the first metal layer overlap.
